(19) United States
(12) Patent Application Publication
(10) Pub. No.: US 2026/0358373 A1
(43) Pub. Date: Nov. 12, 2026

(54) TEST PROBE, PROBE CARD AND MANUFACTURING METHOD OF TEST PROBE

(71) Applicant: XINGR TECHNOLOGIES (ZHEJIANG) LIMITED, JINHUA CITY (CN)

(72) Inventors: CHOON LEONG LOU, Singapore (SG); HO YEH CHEN, ZHUBEI CITY (TW); CHIH-WEI HUNG, Taoyuan City (TW); SUNG MOO CHUN, Hsinchu City (TW)

(73) Assignee: XINGR TECHNOLOGIES (ZHEJIANG) LIMITED, JINHUA CITY (CN)

(21) Appl. No.: 19/384,745

(22) Filed: Nov. 10, 2025

(30) Foreign Application Priority Data
May 9, 2025 (CN) 202510600211.7

(51) Int. Cl. G01R 1/067; G01R 1/073; G01R 3/00

(52) U.S. Cl. CPC G01R 1/06761; G01R 1/07307; G01R 3/00

(57) ABSTRACT

A test probe comprises a probe body, and a coating arranged outside the probe body. The coating contains at least two elements; the contents of the at least two elements vary continuously and linearly in a thickness direction of the coating, so that a conductivity coefficient and a deformation resistance coefficient of the coating vary continuously and linearly in the thickness direction of the coating. In the present disclosure, all the elements that have effects on the conductivity coefficient and the deformation resistance coefficient present in the same coating, which is to say, these elements are connected to form an integral structure. Compared with two stacked alloy coatings of the prior art, the present coating is more robust, and the repeated bending deformation of the test probe will not lead to separation of the coating itself, thus avoiding the degradation of the overall performance of the test probe.

### DESCRIPTION

### CROSS REFERENCE TO RELATED APPLICATIONS

The present application claims the benefits of Chinese Patent Application No. 202510600211.7 filed on May 06, 2025, the entire disclosure of which is incorporated herein by reference.

### FIELD

The present disclosure relates to the technical field of chip test, in particular to a test probe, a probe card and a manufacturing method of the test probe.

### BACKGROUND

Probes are important components for chip signal tests. A probe is usually coated with an alloy coating for improving deformation resistance and an alloy coating for improving conductivity, moreover, the two alloy coatings are arranged sequentially in a stacked manner.

During a signal test with a probe, in order to avoid poor contact of the probe, the substrate presses the probe against the surface of an object to be tested, and the pressure of the substrate causes bending deformation of the probe. Since the above-mentioned two alloy coatings are arranged on the probe in a stacked manner, the repeated bending deformation of the probe will lead to separation between the two alloy coatings, which will further lead to degraded overall performance of the probe.

### SUMMARY

The object of the present disclosure is to overcome the following technical problem: since two alloy coatings are arranged on the probe in a stacked manner, the repeated bending deformation of the probe will lead to separation between the two alloy coatings, which will further lead to degraded overall performance of the probe.

In order to attain the above object, in an aspect, the present disclosure provides a test probe, which comprises a probe body, and a coating arranged outside the probe body, wherein the coating contains at least two elements; the contents of the at least two elements in the coating vary continuously and linearly in a thickness direction of the coating, so that a conductivity coefficient and a deformation resistance coefficient of the coating vary continuously and linearly in the thickness direction of the coating.

In some embodiments, the coating contains two elements; the contents of the two elements in the coating vary continuously and linearly in a thickness direction of the coating, so that a conductivity coefficient and a deformation resistance coefficient of the coating vary continuously and linearly in the thickness direction of the coating.

In some embodiments, the coating contains three elements; the contents of at least two elements in the coating vary continuously and linearly in a thickness direction of the coating, so that a conductivity coefficient and a deformation resistance coefficient of the coating vary continuously and linearly in the thickness direction of the coating.

In some embodiments, each element contained in the coating has a different effect on the conductivity coefficient and/or the deformation resistance coefficient.

In some embodiments, in a linear direction from an inner surface of the coating to an outer surface of the coating, a content of at least one element in the coating increases continuously and linearly, while a content of at least one element in the coating decreases continuously and linearly, so that one of the conductivity coefficient and the deformation resistance coefficient of the coating increases continuously and linearly in the direction, while the other of the conductivity coefficient and the deformation resistance coefficient of the coating decreases continuously and linearly in the direction.

In some embodiments, the coating is attached to an outer surface of the probe body.

In another aspect, the present disclosure further provides a probe card, which comprises a substrate and a plurality of test probes described in the above embodiment, wherein the plurality of test probes are mounted at intervals on the bottom of the substrate.

In yet another aspect, the present disclosure further provides a manufacturing method of a test probe, which comprises the following steps: carrying out an electroplating step on a probe body, and dynamically adjusting electroplating conditions in the electroplating step to form a coating outside the probe body; wherein the contents of at least two elements in the coating vary continuously and linearly in a thickness direction of the coating, so that a conductivity coefficient and a deformation resistance coefficient of the coating vary continuously and linearly in the thickness direction of the coating.

In some embodiments, the dynamically adjusting electroplating conditions at least includes at least one of the following adjustment items: (I) dynamically adjusting a current density of the electroplating with time; (II) dynamically adjusting the concentration of a complexing agent in an electroplating solution with time; (III) dynamically adjusting the temperature of the electroplating solution with time; and (IV) dynamically adjusting the pH value of the electroplating solution with time.

The above technical scheme of the present disclosure has the following technical effects:

The probe body is coated with a coating, which contains at least two elements. In the coating, a content of at least two elements varies continuously and linearly in the thickness direction of the coating, so that a conductivity coefficient and a deformation resistance coefficient of the coating vary continuously and linearly in the thickness direction, thereby the coating can optimize the conductivity and the deformation resistance of the probe body at the same time. In addition, all the elements that have effects on the conductivity coefficient and the deformation resistance coefficient present in the same coating, which is to say, these elements are connected to form an integral structure. Compared with the two alloy coatings arranged in a stacked manner in the prior art, the coating in the present disclosure is more robust, and the repeated bending deformation of the test probe will not lead to separation of the coating itself, thus avoiding the degradation of the overall performance of the test probe.

### BRIEF DESCRITION OF THE DRAWINGS

FIG. 1 is a schematic diagram of the test probe in an embodiment of the present disclosure;

FIG. 2 is a schematic diagram of the variations of the contents of a first element and a second element in an embodiment of the present disclosure;

FIG. 3 is a schematic diagram of the variations of the contents of a first element and a second element in another embodiment of the present disclosure; and

FIG. 4 is a schematic diagram of the variations of the contents of a first element and a second element in yet another embodiment of the present disclosure.

### REFERENCE NUMERALS

1 - probe body; 2 - coating; 21 - coating inner surface; 22 - coating outer surface; 23 - first element; 24 - second element.

### DETAILED DESCRIPTION

The features and exemplary embodiments in various aspects of the present disclosure will be described in detail below. The present disclosure will be further detailed in specific embodiments with reference to the accompanying drawings, to make the object, technical scheme, and advantages of the present disclosure understood more clearly. It may be understood that the embodiments described herein are only intended to explain the present disclosure, but are not intended to limit the present disclosure in any way. It will be apparent to those skilled in the art that the present disclosure can be implemented without some of the specific details. The following description of the embodiments is only intended to provide a better understanding on the present disclosure by showing examples of the present disclosure.

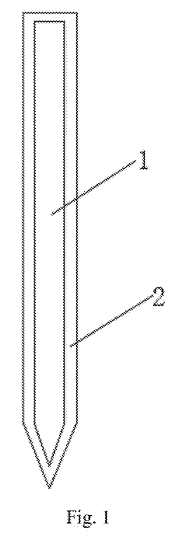

As shown in FIGS. 1-4, in an aspect, the present disclosure provides a test probe, which comprises a probe body 1, and a coating 2 arranged outside the probe body 1, wherein the coating 2 contains at least two elements. The contents of the at least two elements in the coating 2 vary continuously and linearly in a thickness direction of the coating 2, so that a conductivity coefficient and a deformation resistance coefficient of the coating 2 vary continuously and linearly in the thickness direction of the coating 2.

Specifically, the probe body 1 is coated with a coating 2, which contains at least two elements. In the coating 2, the contents of at least two elements vary continuously and linearly in the thickness direction of the coating 2, so that a conductivity coefficient and a deformation resistance coefficient of the coating 2 vary continuously and linearly in the thickness direction, thereby the coating 2 can optimize the conductivity and the deformation resistance of the probe body 1 at the same time. In addition, all the elements that affect the conductivity coefficient and the deformation resistance coefficient present in the same coating 2, which is to say, these elements are formed a single piece . Compared with the two alloy coatings arranged in a stacked manner in the prior art, the coating 2 in the present disclosure is more robust, and the repeated bending deformation of the test probe will not lead to separation of the coating 2 itself, thus avoiding the degradation of the overall performance of the test probe.

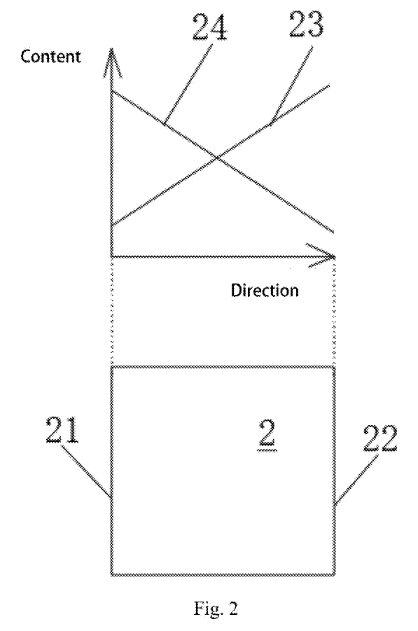

As shown in FIGS. 2-4, in some embodiments of the present disclosure, the coating 2 contains two elements; the contents of the two elements in the coating 2 vary continuously and linearly in the thickness direction of the coating 2, so that a conductivity coefficient and a deformation resistance coefficient of the coating 2 vary continuously and linearly in the thickness direction of the coating 2.

Specifically, both the two elements that affect the conductivity coefficient and the deformation resistance coefficient are in the same coating 2, which is to say, the two elements are formed a single piece, so that the coating 2 can optimize the conductivity and the deformation resistance of the probe body 1 at the same time, for example, it can optimize the thermal conductivity, the magnetic conductivity, the electrical conductivity, the hardness and the strength, etc. at the same time.

For example, in some embodiments, as shown in FIGS. 2-4, the coating 2 contains two elements, wherein a first element 23 is cobalt and a second element 24 is nickel. The content of the cobalt element varies continuously and linearly in the thickness direction of the coating 2, so that the deformation resistance coefficient of the coating 2 varies continuously and linearly in the thickness direction of the coating 2; the content of the nickel element varies continuously and linearly, so that the conductivity coefficient of the coating 2 varies continuously and linearly in the thickness direction of the coating 2. Alternatively, there may be two other elements in the coating 2, such as copper and chromium. There is no particular restriction on the elements in the coating 2 in the present disclosure.

In some embodiments of the present disclosure, the coating 2 contains three elements. The contents of at least two elements in the coating 2 vary continuously and linearly in the thickness direction of the coating 2, so that a conductivity coefficient and a deformation resistance coefficient of the coating 2 vary continuously and linearly in the thickness direction of the coating 2.

Specifically, among the three elements, two or three elements may affect the conductivity coefficient and the deformation resistance coefficient. Alternatively, all elements that affect the conductivity coefficient and the deformation resistance coefficient are in the same coating 2, which is to say, the two elements are formed a single piece, so that the coating 2 can optimize the conductivity and the deformation resistance of the probe body 1 at the same time, for example, it can optimize the thermal conductivity, the magnetic conductivity, the electrical conductivity, the hardness and the strength, etc. at the same time.

For example, in some embodiments, as shown in FIG. 2, the coating 2 contains three elements, wherein a first element 23 is cobalt, a second element 24 is nickel, and a third element is ferrum. The content of the cobalt element varies continuously and linearly in the thickness direction of the coating 2, so that the deformation resistance coefficient of the coating 2 varies continuously and linearly in the thickness direction of the coating 2; at the same time, the content of the nickel element varies continuously and linearly, so that the conductivity coefficient of the coating 2 varies continuously and linearly in the thickness direction of the coating 2; while the content of the ferrum element may vary continuously and linearly or remains constant. Alternatively, there may be three other elements in the coating 2, such as palladium, silver and copper. There is no particular restriction on the elements in the coating 2 in the present disclosure.

In some embodiments of the present disclosure, each element contained in the coating has a different effect on the conductivity coefficient and/or the deformation resistance coefficient.

Specifically, each element in the coating may affect the conductivity coefficient and/or the deformation resistance coefficient. For example, one of the elements may affect the conductivity coefficient or the deformation resistance coefficient; for another example, one of the elements may affect the conductivity coefficient and the deformation resistance coefficient simultaneously. In addition, as the content of the element varies, the effect of the element on the conductivity efficient and/or the deformation resistance coefficient also varies. Finally, under the comprehensive effects of various elements, the conductivity coefficient and the deformation resistance coefficient of the coating 2 vary continuously and linearly in the thickness direction of the coating 2, so that the coating 2 can optimize the conductivity and deformation resistance of the probe body 1 at the same time, for example, it can optimize the thermal conductivity, the magnetic conductivity, the electrical conductivity, the hardness and the strength, etc.

For example, in some embodiments, the coating 2 contains a cobalt element and a nickel element. The cobalt element mainly affects the deformation resistance coefficient, thereby affecting the hardness and the strength, etc. The nickel element mainly affects the conductivity coefficient, thereby affects the thermal conductivity, the magnetic conductivity and the electrical conductivity, etc.

As shown in FIG. 2, in some embodiments of the present disclosure, in a linear direction from an inner surface of the coating 2 to an outer surface of the coating 2, the content of a first element 23 in the coating 2 increases continuously and linearly, while the content of a second element 24 in the coating 2 decreases continuously and linearly, so that one of the conductivity coefficient and the deformation resistance coefficient of the coating 2 increases continuously and linearly in the direction, while the other of the conductivity coefficient and the deformation resistance coefficient of the coating 2 decreases continuously and linearly in the direction.

Specifically, the coating 2 may contain two, three or more elements. All elements that affect the conductivity coefficient and the deformation resistance coefficient are in the same coating 2, which is to say, these elements are formed a single piece, so that the coating 2 can optimize the conductivity and the deformation resistance of the probe body 1 at the same time, for example, it can optimize the thermal conductivity, the magnetic conductivity, the electrical conductivity, the hardness and the strength, etc. at the same time. In addition, the content of at least one element increases continuously and linearly, while the content of at least one element decreases continuously and linearly, so that the trends of variations of the content of each main constituent element in the coating 2 are relatively stable, and the entire coating 2 is a single-layer structure, which is helpful for making the coating 2 more stable and more robust.

For example, in some embodiments, as shown in FIG. 2, the coating 2 contains three elements, wherein a first element 23 is cobalt, a second element 24 is nickel, and a third element is ferrum. The inner surface of the coating 2 is defined as a coating inner surface 21, and the outer surface of the coating 2 is defined as a coating outer surface 22. In a linear direction from the coating inner surface 21 to the coating outer surface 22, the content of the cobalt element increases linearly, so that the deformation resistance coefficient of the coating 2 increases continuously and linearly; the content of the nickel element decreases linearly, so that the conductivity coefficient of the coating 2 decreases continuously and linearly; the content of the ferrum element may remain stable, increase continuously and linearly, or decrease continuously and linearly.

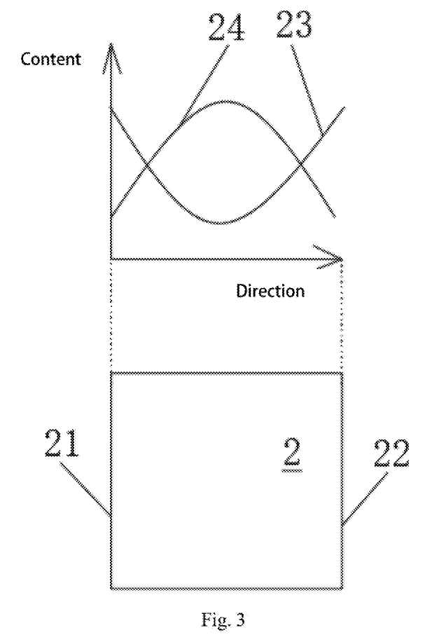

In some other embodiments, as shown in FIG. 3, in a linear direction from the coating inner surface 21 to the coating outer surface 22, the content of at least one element decreases first and increases then, and its trend of variation is generally a continuous curve with an upward opening; the content of at least one other element increases first and decreases then, and its trend of variation is generally a continuous curve with a downward opening. For example, as shown in FIG. 3, the trend of variation of the content of the first element 23 is a continuous curve with an upward opening, and the trend of variation of the content of the second element 24 is a continuous curve with a downward opening. Of course, in these embodiments, the coating 2 may also contain two, three or more elements.

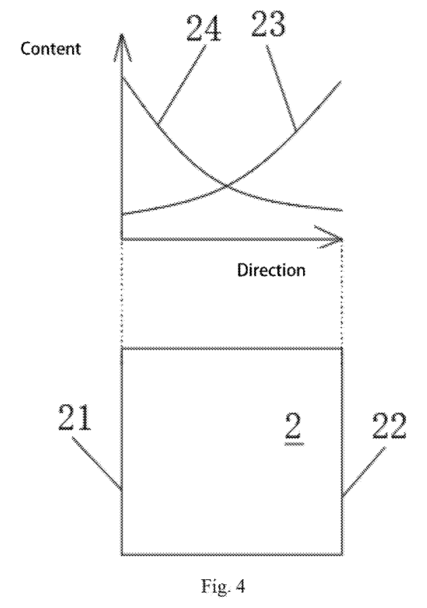

Of course, the trends of variations of the content of each element in the coating 2 may be in other forms. There is no particular restriction on the trends of variations of the content of each element in the coating 2 in the present disclosure. For example, as shown in FIG. 4, the trend of variation of the content of an element may be a continuous curve that is roughly similar to the image of an exponential function.

In some embodiments of the present disclosure, the materials selected for the coating 2 include at least one of gold (Au), silver (Ag), copper (Cu), nickel (Ni), chromium (Cr), platinum (Pt), palladium (Pd), ferrum (Fe), tantalum (Ta), zirconium (Zr), aluminum (Al), rhodium (Rh), molybdenum (Mo), titanium (Ti), ruthenium (Ru), cobalt (Co), zinc (Zn), tungsten carbide (WC), diamond-like carbon (DLC) and titanium nitride (TiN). Of course, other materials may also be selected. There is no particular restriction on the selection of the materials in the present disclosure.

In some embodiments, each material in the coating 2 may exist as a single substance, and the coating 2 is made of a mixture of at least two single substances, such as a mixture of a nickel metal material and a cobalt metal material.

In some other embodiments, each element in the coating 2 may exist in the form of solid solution alloy or intermetallic compound alloy, which is to say, the coating 2 is made of an alloy material composed of at least two elements, such as a nickel-cobalt (Ni-Co) alloy material, a nickel-boron (Ni-B) alloy material, a platinum-nickel (Pt-Ni) alloy material, a copper-silver (Cu-Ag) alloy material, a palladium-silver-copper (Pd-Ag-Cu) alloy material, or a phosphorus-palladium (Pd-P) alloy material, etc.

As shown in FIG. 1, in some embodiments of the present disclosure, the coating 2 is attached to the outer surface of the probe body 1, so that the coating 2 is firmly connected to the probe body 1. For example, the coating 2 may be formed on the outer surface of the probe body 1 through an electroplating process.

In some embodiments, the outer surface of the probe body 1 is fully coated by the coating 2. In some other embodiments, only the outer surface of the middle and lower part of the probe body 1 is fully coated by the coating 2.

In some embodiments, when a cross section is taken in a direction perpendicular to the length direction of the probe body 1, the cross section of the probe body 1 is circular, and the cross section of the coating 2 is annular; alternatively, the cross section of the probe body 1 is rectangular, and the cross section of the coating 2 is a square ring. Alternatively, the cross section of the probe body 1 and the cross section of the coating 2 may be in other shapes. There is no particular restriction on the shapes of their cross sections.

In another aspect, the present disclosure further provides a probe card, which comprises a substrate and a plurality of test probes described in the above embodiment, wherein the plurality of test probes are mounted at intervals on the bottom of the substrate.

Specifically, the probe card in the present disclosure employs the test probe described in the above embodiment. Therefore, the probe card can also achieve the above technical effects.

In some embodiments, the coating 2 in the present disclosure may be plated on an interface of another coating on the probe body 1. Likewise, there will be no lamination between the elements in the coating 2 in the present disclosure. In some embodiments, other coating may be other electrical conductors or insulating layers.

In yet another aspect, the present disclosure further provides a manufacturing method of a test probe, which comprises the following steps: carrying out an electroplating step on a probe body 1, and dynamically adjusting electroplating conditions in the electroplating step to form a coating 2 outside the probe body 1; wherein the contents of at least two elements in the coating 2 vary continuously and linearly in a thickness direction of the coating 2, so that a conductivity coefficient and a deformation resistance coefficient of the coating 2 vary continuously and linearly in the thickness direction of the coating 2.

Specifically, by dynamically adjusting the electroplating conditions in the electroplating step, a coating 2 containing at least two elements is formed outside the probe body 1. In the coating 2, the contents of the at least two elements vary continuously and linearly in the thickness direction of the coating 2, so that a conductivity coefficient and a deformation resistance coefficient of the coating 2 vary continuously and linearly in the thickness direction, thereby the coating 2 can optimize the conductivity and the deformation resistance of the probe body 1 at the same time, for example, it can optimize the thermal conductivity, the magnetic conductivity, the electrical conductivity, the hardness and the strength, etc. at the same time. In addition, all the elements that affect the conductivity coefficient and the deformation resistance coefficient present in the same coating 2, which is to say, these elements are formed a single piece. Compared with the two alloy coatings 2 arranged in a stacked manner in the prior art, the coating 2 in the present disclosure is more robust, and the repeated bending deformation of the test probe will not lead to separation of the coating 2 itself, thus avoiding the degradation of the overall performance of the test probe.

In some embodiments of the present disclosure, the dynamically adjusting electroplating conditions at least includes at least one of the following adjustment items: (I) dynamically adjusting a current density (ASD) of the electroplating with time; (II) dynamically adjusting the concentration of a complexing agent in an electroplating solution with time; (III) dynamically adjusting the temperature of the electroplating solution with time; and (IV) dynamically adjusting the pH value of the electroplating solution with time.

Specifically, by adjusting at least one of the above items, the amounts of at least two elements plated on the probe body 1 can vary continuously and linearly. Thus, after the coating 2 is formed, the contents of at least two elements vary continuously and linearly in the thickness direction.

In some embodiments of the present disclosure, the each material selected for the plating may include at least one of gold (Au), silver (Ag), copper (Cu), nickel (Ni), chromium (Cr), platinum (Pt), palladium (Pd), ferrum (Fe), tantalum (Ta), zirconium (Zr), aluminum (Al), rhodium (Rh), molybdenum (Mo), titanium (Ti), ruthenium (Ru), cobalt (Co), zinc (Zn), tungsten carbide (WC), diamond-like carbon (DLC) and titanium nitride (TiN). Of course, other materials may also be selected for the plating. There is no particular restriction on the selection of the materials in the present disclosure.

While the principle and embodiments of the present disclosure are described herein in specific examples, the description of those examples is only intended to assist in understanding the method and core idea of the present disclosure. The above embodiments are only some preferred embodiments of the present disclosure. It may be noted that objectively numerous specific structures may exist though the literal expression is limited. Those having ordinary skills in the art can make various improvements, modifications or variations, and combine the above-mentioned technical features in appropriate ways, without departing from the principle of the present disclosure; however, those improvements, modifications, variations, or combinations, or direct application of the inventive concept and technical scheme of the present disclosure to other scenarios without improvement shall be deemed as falling in the scope of protection of the present disclosure.

1. A test probe, comprising a probe body (1), and a coating (2) arranged outside the probe body (1), wherein the coating (2) contains at least two elements;
contents of the at least two elements in the coating (2) vary continuously and linearly in a thickness direction of the coating (2), so that a conductivity coefficient and a deformation resistance coefficient of the coating (2) vary continuously and linearly in the thickness direction of the coating (2).

2. The test probe according to claim 1, wherein the coating (2) contains two elements; the contents of the two elements in the coating (2) vary continuously and linearly in the thickness direction of the coating (2), so that the conductivity coefficient and the deformation resistance coefficient of the coating (2) vary continuously and linearly in the thickness direction of the coating (2).

3. The test probe according to claim 1, wherein the coating (2) contains three elements; the contents of at least two elements in the coating (2) vary continuously and linearly in the thickness direction of the coating (2), so that the conductivity coefficient and the deformation resistance coefficient of the coating (2) vary continuously and linearly in the thickness direction of the coating (2).

4. The test probe according to claim 1, wherein each element contained in the coating (2) has a different effect on the conductivity coefficient and/or the deformation resistance coefficient.

5. The test probe according to claim 1, wherein in a linear direction from an inner surface of the coating (2) to an outer surface of the coating (2), a content of a first element in the coating (2) increases continuously and linearly, while a content of a second element in the coating (2) decreases continuously and linearly, so that one of the conductivity coefficient and the deformation resistance coefficient of the coating (2) increases continuously and linearly in the linear direction, while the other of the conductivity coefficient and the deformation resistance coefficient of the coating (2) decreases continuously and linearly in the linear direction.

6. The test probe according to claim 1, wherein the coating (2) is attached to an outer surface of the probe body (1).

7. A probe card comprising a substrate and a plurality of test probes according to claim 1, wherein the plurality of test probes are mounted at intervals on the bottom of the substrate.

8. A manufacturing method of a test probe, comprising: carrying out an electroplating step on a probe body (1), and dynamically adjusting electroplating conditions in the electroplating step to form a coating (2) outside the probe body (1); and contents of at least two elements in the coating (2) vary continuously and linearly in a thickness direction of the coating (2), so that a conductivity coefficient and a deformation resistance coefficient of the coating (2) vary continuously and linearly in the thickness direction of the coating (2).

9. The test probe according to claim 8, wherein the dynamically adjusting electroplating conditions includes at least one of following adjustment items:
(I) dynamically adjusting a current density of the electroplating with time;
(II) dynamically adjusting the concentration of a complexing agent in an electroplating solution with time;
(III) dynamically adjusting the temperature of the electroplating solution with time; and
(IV) dynamically adjusting the pH value of the electroplating solution with time.
